(19) United States
(12) Patent Application Publication
(10) Pub. No.: US 2026/0164902 A1
(43) Pub. Date: Jun. 11, 2026

(54) DISPLAY DEVICE

(71) Applicant: AUO Corporation, Hsinchu City (TW)

(72) Inventors: Yi-Sheng JHAO, Hsinchu City (TW); Kuan-Hsun CHEN, Hsinchu City (TW)

(21) Appl. No.: 19/371,638

(22) Filed: Oct. 28, 2025

(30) Foreign Application Priority Data
Dec. 9, 2024 (TW) 113147739

(51) Int. Cl. H10H 29/855; H10H 29/49

(52) U.S. Cl. CPC H10H 29/8552; H10H 29/49

(57) ABSTRACT

A display device which includes a driver circuit substrate, a plurality of light-emitting components and a light shielding pattern layer is provided. The light-emitting components are disposed on and electrically connected to the driver circuit substrate. The light shielding pattern layer is disposed on the driver circuit substrate, and the light-emitting components are exposed. The light shielding pattern layer has a first surface and a second surface which backs on to the driver circuit substrate, and at least two of the light-emitting components are exposed on the first surface and the second surface separately. The distance between the first surface and the driver circuit substrate is smaller than the distance between the second surface and the driver circuit substrate.

### RELATED APPLICATIONS

This application claims priority to Taiwan Application Serial Number 113147739, filed Dec. 9, 2024, which is herein incorporated by reference in its entirety.

### BACKGROUND

### Technical field

The present disclosure relates to a display device.

### Description of Related Art

Splicing technology is one of the main methods for achieving large format display (LFD). This technology is to splice a plurality of smaller display panels to assemble a larger display. Generally, a brand or a manufacturer's trademark can be shown on a seamlessly spliced display (e.g., a micro LED display) by disposing a special frame and printing the trademark on this frame. However, since the frame occupies a certain area, the area which is not used for displaying images on the display increases, thereby reducing the area utilization of the display device. Furthermore, in order to maintain the continuity of the image on large format displays, the frame should be placed at the edge of the display, so that the position for the trademark is limited.

### SUMMARY

Accordingly, the disclosure is to provide a display device which is advantage for increasing the area utilization of the display device.

At least one embodiment of the disclosure provides a display device including a driver circuit substrate, a plurality of light-emitting components and a light shielding pattern layer. The plurality of light-emitting components are disposed on the driver circuit substrate and electrically connected to the driver circuit substrate. The light shielding pattern layer is disposed on the driver circuit substrate, and the plurality of light-emitting components are exposed. The light shielding pattern layer has a first surface and a second surface back on to the driver circuit substrate, and at least two of the plurality of light-emitting components are exposed on the first surface and the second surface separately. A distance between the first surface and the driver circuit substrate is smaller than a distance between the second surface and the driver circuit substrate.

At least in one embodiment of the disclosure, a spacing between the first surface and the second surface of the light shielding pattern layer is larger than 0.4 μm.

At least in one embodiment of the disclosure, a spacing between the first surface and the second surface of the light shielding pattern layer is equal to 0.4 μm.

At least in one embodiment of the disclosure, the first surface and the second surface of the light shielding pattern layer have a roughness, and the roughness is between 0.05 μm and 0.5 82 m.

At least in one embodiment of the disclosure, the first surface of the light shielding pattern layer shapes as words or trademark patterns.

At least in one embodiment of the disclosure, each of the plurality of light-emitting components has a top surface backing on to the driver circuit substrate, and a distance between the second surface of the light shielding pattern layer and the driver circuit substrate is smaller than a distance between the top surface and the driver circuit substrate. A spacing is between the second surface and the top surface, and the spacing is larger than 1 μm.

At least in one embodiment of the disclosure, the display device further includes a plurality of pads disposed on the plurality of light-emitting components separately and located between the driver circuit substrate and the plurality of light-emitting components. The plurality of light-emitting components are electrically connected to the driver circuit substrate through the plurality of pads, and each of the plurality of pads has a top surface backing on to the driver circuit substrate. A distance between the top surface and the driver circuit substrate is smaller than a distance between the first surface and driver circuit substrate.

At least in one embodiment of the disclosure, the display device further includes an optical film disposed on the light shielding pattern layer and the plurality of light-emitting components and covering the first surface and the second surface of the light shielding pattern layer and the plurality of light-emitting components.

At least in one embodiment of the disclosure, the display device further includes an adhesive material disposed on the light shielding pattern layer and located between the optical film and the driver circuit substrate.

At least in one embodiment of the disclosure, the light shielding pattern layer is an opaque encapsulation layer, and the encapsulation layer is distributed between the plurality of light-emitting components.

At least one embodiment of the disclosure provides a display device including a driver circuit substrate, a plurality of light-emitting components and a light shielding pattern layer. The plurality of light-emitting components are disposed on the driver circuit substrate and electrically connected to the driver circuit substrate. The light shielding pattern layer is disposed on the driver circuit substrate, and the plurality of light-emitting components are exposed. The light shielding pattern layer has a first surface and a second surface back on to the driver circuit substrate, and at least two of the plurality of light-emitting components are exposed on the first surface and the second surface separately. A first spacing between the first surface and the second surface of the light shielding pattern layer is larger than 0.4 μm.

At least in one embodiment of the disclosure, each of the plurality of light-emitting components has a top surface backing on to the driver circuit substrate, and a distance between the second surface of the light shielding pattern layer and the driver circuit substrate is smaller than a distance between the top surface and the driver circuit substrate. A second spacing is between the second surface and the top surface, and the second spacing is larger than 1 μm.

According to the aforementioned embodiments, a vision difference is created by the height difference between the first surface and the second surface of the light shielding pattern layer. Therefore, when the light-emitting components are turned off, the trademark or model pattern of the product can be shown on the display surface of the display device. Since the light-emitting components are exposed on the first surface and the second surface of the light shielding pattern layer, the light rays emitted by the light-emitting components will not be shielded by the light shielding pattern layer as the light-emitting components are turned on. Thus, the user's vision will not be affected. As a result, the trademark or the model pattern of the product can be shown on the display surface area of the display device without any limitation by the bezel of the display device, thereby increasing the area utilization of the display device.

### BRIEF DESCRIPTION OF THE DRAWINGS

To illustrate more clearly the aforementioned and the other objects, features, merits, and embodiments of the present disclosure, the description of the accompanying figures are as follows:

FIG. 1 illustrates a top view of a display device in accordance with one embodiment of the present disclosure.

FIG. 2A illustrates a cross-sectional view of the display device along with the line A-A of FIG. 1.

FIG. 2B illustrates a locally cross-sectional view of the first surface of the display device in accordance with another embodiment of the present disclosure

FIG. 3 illustrates a locally top view of the light shielding pattern layer in accordance with another embodiment of the present disclosure.

FIG. 4 illustrates a cross-sectional view of the light shielding pattern layer along with the line B-B of FIG. 3.

FIG. 5A to FIG. 5C illustrate sequent steps of this method in accordance with at least one embodiment of present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. In addition, the number or range of numbers encompasses a reasonable range including the number described, such as within +/−30%, +/−20%, +/−10% or +/−5% of the number described, based on known manufacturing tolerances associated with manufacturing a feature having a characteristic associated with the number. The words of deviations such as “about,” “approximate,” “substantially,” and the like are chosen in accordance with the optical properties, etching properties, mechanical properties or other properties. The words of deviations used in the optical properties, etching properties, mechanical properties or other properties are not chosen with a single standard.

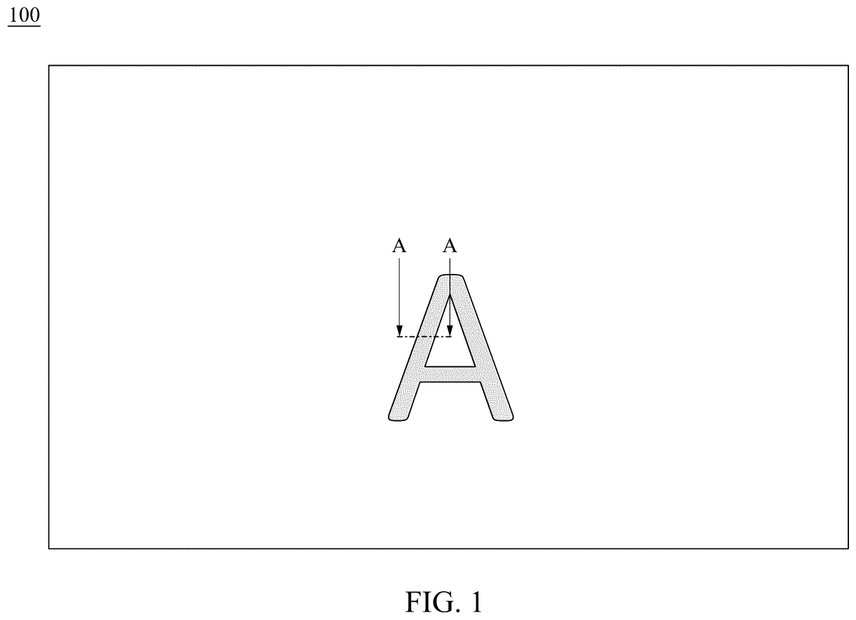

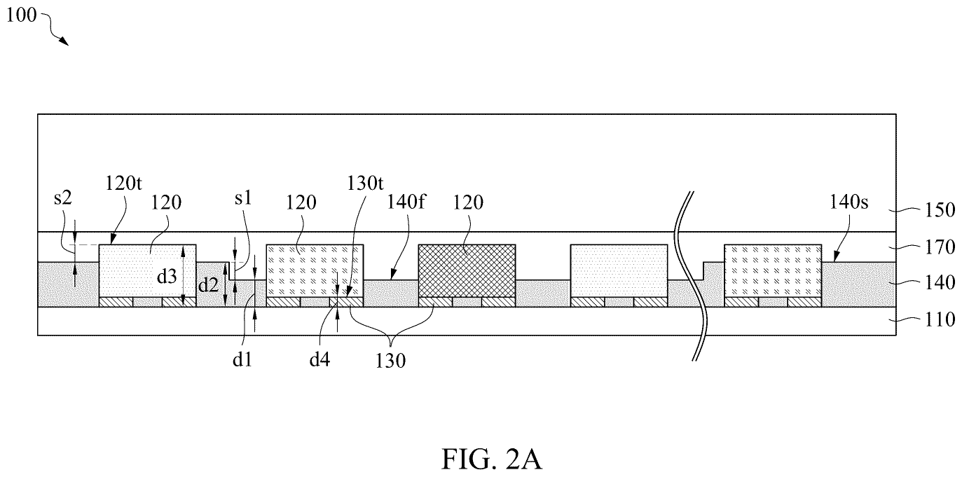

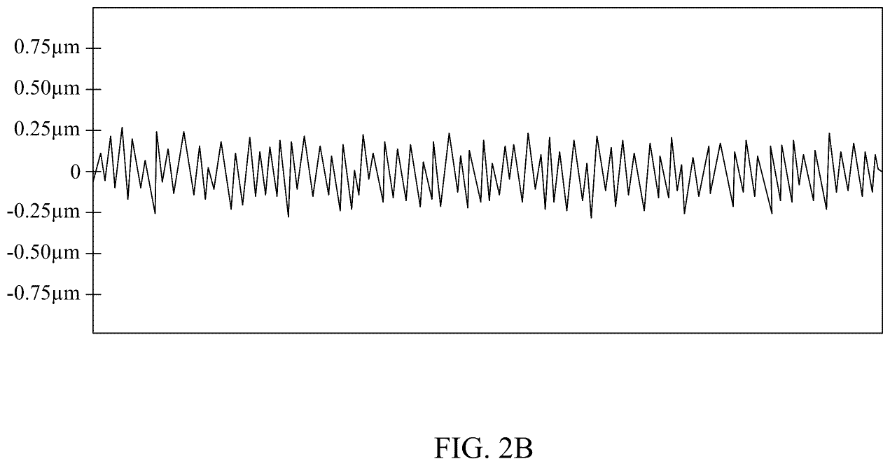

FIG. 1 illustrates a top view of a display device 100 in accordance with one embodiment of the present disclosure, while FIG. 2A illustrates a cross-sectional view of the display device 100 along with the line A-A of FIG. 1. Referring to FIG. 1 and FIG. 2A, the display device 100 includes a driver circuit substrate 110, a plurality of light-emitting components 120 and a light shielding pattern layer 140. The light-emitting components 120 are disposed on the driver circuit substrate 110 and electrically connected to the driver circuit substrate 110. The driver circuit substrate 110 may be such as a thin film transistor (TFT) array substrate or a similar pixel array substrate. In addition, the light-emitting components 120 may be such as organic light emitting diodes (OLED), micro LEDs or similar LEDs.

The light-emitting components 120 may emit light rays with different wavelengths, respectively. For instance, the light-emitting components 120 may be red light LEDs, green light LEDs and blue light LEDs. The aforementioned LEDs emitting light with different color are arranged alternately. Each one of the LEDs may be seen as a sub-pixel of the display device 100, while one red light LED, one green light LED and one blue light LED which are adjacent to each other may be defined as one pixel (i.e., a main pixel) of the display device 100. It is worth mentioning, the range of wavelength of the light rays emitted by the light-emitting components 120 are not limited to the embodiment (e.g., at least one of the light-emitting components 120 may be a yellow light LED).

The light shielding pattern layer 140 is disposed on the driver circuit substrate 110, while the light-emitting components 120 are exposed. The light shielding pattern layer 140 has a first surface 140f and a second surface 140s, and at least two of the light-emitting components 120 are exposed on the first surface 140f and the second surface 140s separately. Take the embodiment of FIG. 2A as an example, three of the light-emitting components 120 (i.e., the three light-emitting components 120 in the middle) are exposed on the first surface 140f of the light shielding pattern layer 140, while the other two light-emitting components 120 (i.e., the two light-emitting components 120 on the left and right) are exposed on the second surface 140s of the light shielding pattern layer 140. The light shielding pattern layer 140 is an opaque encapsulation layer (e.g., black glues), and this encapsulation layer is distributed between the light-emitting components 120, so as to bond the light-emitting components 120 on the driver circuit substrate 110. In addition, the materials of the light shielding pattern layer 140 may include black bonding adhesives, black pigment inks or similar encapsulation materials.

As shown in FIG. 2A, a distance d1 between the first surface 140f and the driver circuit substrate 110 is smaller than a distance d2 between the second surface 140s and the driver circuit substrate 110. In other words, the first surface 140f of the light shielding pattern layer 140 recesses from the second surface 140s. In the embodiment, a spacing s1 between the first surface 140f and the second surface 140s of the light shielding pattern layer 140 is larger than or equal to 0.4 μm, but the disclosure is not limited to this embodiment. In other embodiments, the spacing s1 between the first surface 140f and the second surface 140s may be smaller than 0.4 μm. For instance, the distance d1 between the first surface 140f and the driver circuit substrate 110 may be between 2.0 μm and 79.6 μm, while the distance d2 between the second surface 140s and the driver circuit substrate 110 may be between 2.4 μm and 80 μm.

It is worth mentioning, although the first surface 140f and the second surface 140s shown in FIG. 2A are smooth surfaces, the disclosure is not limited to the embodiment. In some embodiments, the first surface 140f and the second surface 140s of the light shielding pattern layer 140 are substantially rough surfaces. FIG. 2B illustrates a locally cross-sectional view of the first surface of the display device in accordance with another embodiment of the present disclosure. As shown in FIG. 2B, the first surface 140f and the second surface 140s of the light shielding pattern layer 140 have a roughness which is between 0.05 μm and 0.5 μm.

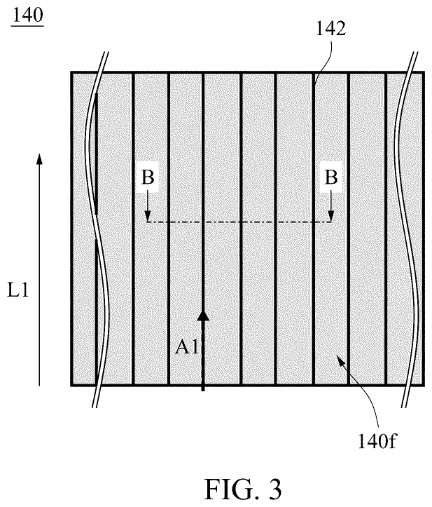

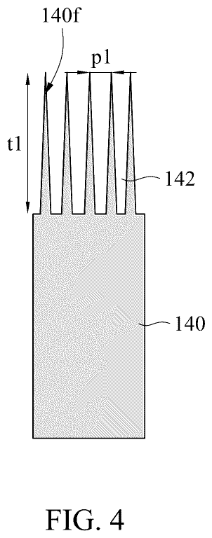

FIG. 3 illustrates a locally top view of the light shielding pattern layer in accordance with another embodiment of the present disclosure, while FIG. 4 illustrates a cross-sectional view of the light shielding pattern layer 140 along with the line B-B of FIG. 3. Referring to FIG. 3 and FIG. 4, in the embodiment, the first surface 140f of the light shielding pattern layer 140 includes a plurality of strip trenches 142 juxtaposed to each other, and the strip trenches 142 extend along with a long axis direction A1. Each of the strip trenches 142 has a depth t1, and the depth t1 is between 0.05 μm and 80 μm. In addition, a plurality of pitches p1 are separately located between two of the strip trenches 142 adjacent to each other, and the pitches p1 are between 1 μm and 30 μm. The variance of the pitches p1 is smaller than 10%.

It is worth mentioning, the strip trenches 142 in the embodiment may be scratches from laser cutting. Specifically, when the first surface 140f is cut by laser, and the tracing direction of laser beams is defined as L1, the strip trenches 142 are formed on the first surface 140f. As a result, the long axis direction A1 is the same as the tracing direction L1 of laser beams. In addition, the second surface 140s of the light shielding pattern layer 140 in the embodiment has a roughness which is between 0.05 μm and 0.5 μm.

In various embodiments, the first surface 140f of the light shielding pattern layer 140 may shape as words or trademark patterns. For instance, when the display device 100 is a product of corporation A, the first surface 140f of the light shielding pattern layer 140 on the display device 100 may shape as the trademark or the name of the corporation (e.g., the pattern A in FIG. 1). Furthermore, the display device 100 may be a certain model of the corporation A, such as model X, so that the first surface 140f of the light shielding pattern layer 140 may shape as the name (e.g., model X) of the model. In various embodiments, the words or patterns that the first surface 140f of the light shielding pattern layer 140 shapes as are not limited to aforementioned examples.

Referring to FIG. 2A, each of the light-emitting components 120 has a top surface 120t backing on to the driver circuit substrate 110. In the embodiment, the distance d2 between the second surface 140s of the light shielding pattern layer 140 and the driver circuit substrate 110 is smaller than a distance d3 between the top surface 120t and the driver circuit substrate 110. In other words, the second surface 140s of the light shielding pattern layer 140 recesses from the top surface 120t of the light-emitting components 120. It is worth mentioning, the top surface 120t of each light-emitting component 120 is exposed on the first surface 140f and the second surface 140s of the light shielding pattern layer 140, so that the light rays emitted by the light-emitting components 120 will not be shielded by the light shielding pattern layer 140.

In the embodiment, a spacing s2 is between the second surface 140s of the light shielding pattern layer 140 and the top surface 120t of the light-emitting components 120, and the spacing s2 is larger than 1 μm. However, the disclosure is not limited to the embodiment. In other embodiments, the spacing s2 between the second surface 140s of the light shielding pattern layer 140 and the top surface 120t of the light-emitting components 120 may be smaller than or equal to 1 μm. For instance, the distance d3 between the top surface 120t and the driver circuit substrate 110 may be between 6 μm and 80 μm.

In addition, the display device 100 in the embodiment further includes a plurality of pads 130. The pads 130 are disposed on the light-emitting components 120 separately and located between the driver circuit substrate 110 and the light-emitting components 120. The light-emitting components 120 are electrically connected to the driver circuit substrate 110 through the pads 130, and each of the pads 130 has a top surface 130t backing on to the driver circuit substrate 110. A distance d4 between the top surface 130t and the driver circuit substrate 110 is smaller than the distance d1 between the first surface 140f and the driver circuit substrate 110. In other words, the top surface 130t of the pads 130 recesses from the first surface 140f of the light shielding pattern layer 140. Since the pads 130 may be encapsulated by light shielding pattern layer 140, the pads 130 are bonded on the driver circuit substrate 110.

Referring to FIG. 2A, the display device 100 further includes an optical film 150. The optical film 150 is disposed on the light shielding pattern layer 140 and the light-emitting components 120 while covers the first surface 140f, the second surface 140s of the light shielding pattern layer 140 and the light-emitting components 120. The light rays emitted by the light-emitting components 120 may pass through the optical film 150, and the light-emitting effect (including the light-emitting pattern and the uniformity) may be adjusted by the optical film 150. For instance, the optical film 150 may include prism sheet or diffusion sheet.

In addition, since the optical film 150 is disposed on the light-emitting components 120, the display device 100 further includes an adhesive material 170 in order to bond the optical film 150 on the light-emitting components 120 and to prevent the light-emitting components 120 from being damaged by crush of the optical film 150. The adhesive material 170 is disposed on the light shielding pattern layer 140 and located between the optical film 150 and the driver circuit substrate 110. The adhesive material 170 encapsulates the surfaces of the light-emitting components 120 to protect the light-emitting components 120. The adhesive material 170 may be encapsulation adhesives, such as optical clear adhesives (OCA) or other similar transparent materials.

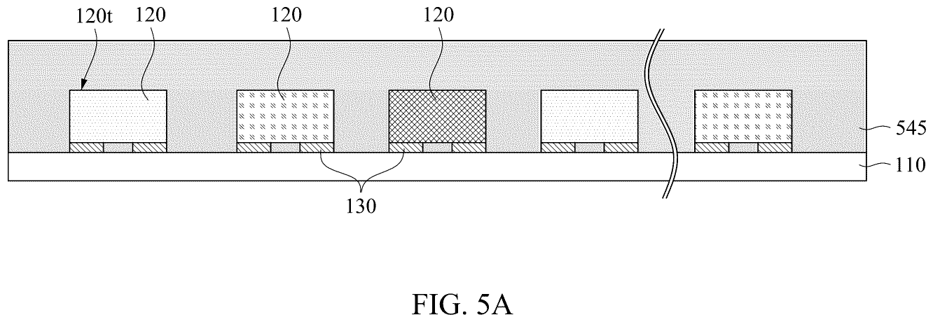

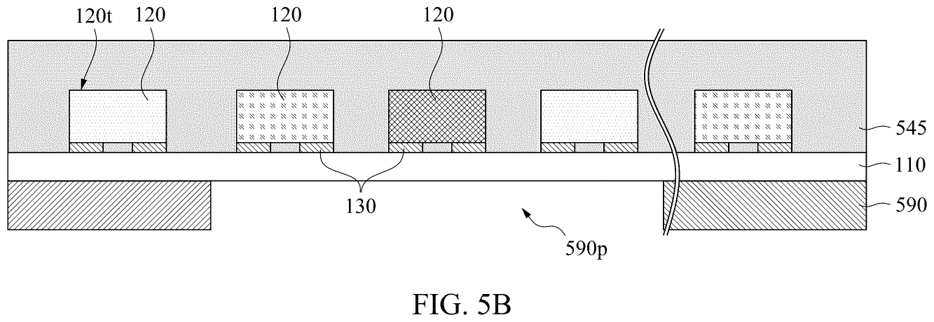

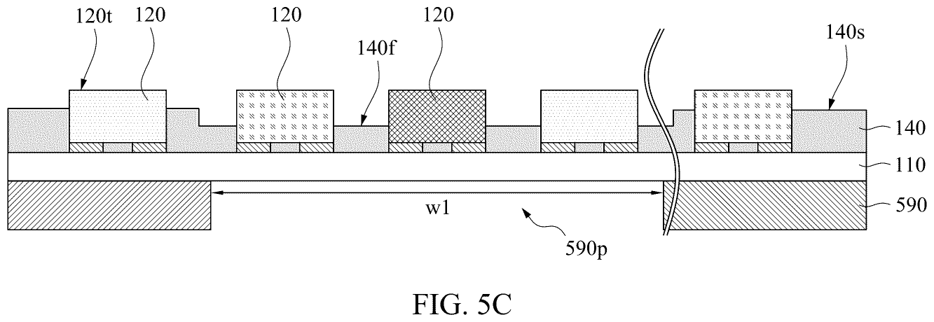

A method for fabrication of the display device 100 is disclosed, while FIG. 5A to FIG. 5C illustrate sequent steps of this method in accordance with at least one embodiment of present disclosure. Referring to FIG. 5A, firstly, the driver circuit substrate 110 is provided. Next, the plurality of light-emitting components 120 are disposed on the driver circuit substrate 110, while the light-emitting components 120 are electrically connected to the driver circuit substrate 110. A light shielding material 545 is formed on the driver circuit substrate 110 by methods, such as lamination or spray coating, after the light-emitting components 120 are disposed on the driver circuit substrate 110. The light shielding material 545 covers the top surface 120t of the light-emitting components 120.

Referring to FIG. 5B and FIG. 1, a mold 590 is disposed on another surface of the driver circuit substrate 110 after the light shielding material 545 is formed on the driver circuit substrate 110, so that the light-emitting components 120 and the mold 590 are located on two opposite sides of the driver circuit substrate 110 separately. The mold 590 has an opening 590p, and the opening 590p completely overlaps the first surface 140f of the light shielding pattern layer 140 in FIG. 1. That is, the opening 590p of the mold 590 shapes as the same words or patterns as the first surface 140f.

Next, referring to FIG. 5C, the light shielding material 545 is etched by plasma etching (e.g., microwave plasma etching) after the mold 590 is disposed on the driver circuit substrate 110, so as to form the light shielding pattern layer 140 shown in FIG. 2A. It is worth mentioning, the mold 590 may include materials, such as aluminum, ceramic or other similar materials whose thermal conductivity is between 0.1 W/mK and 6000 W/mK. The heat in the light shielding material 545 may be transfer to the external area through the mold 590. Since a region of the light shielding material 545 overlaps the mold 590, while the other region of the light shielding material 545 overlaps the opening 590p, the heat dissipation efficiency of these two regions are different.

Specifically, the heat dissipation efficiency of the light shielding material 545 that overlaps the mold 590 may be higher than the heat dissipation efficiency of the light shielding material 545 that overlaps the opening 590p. As a result, the temperature of the light shielding material 545 that overlaps the mold 590 is lower than the temperature of the light shielding material 545 that overlaps the opening 590p.

During the process of the plasma etching, the etching rate is affected by different environmental temperature, resulting in different etching depths. Since the heat dissipation efficiency of the aforementioned two regions of the light shielding material 545 are different (the temperature of the two regions are therefore different), the depth of the light shielding material 545 formed by etching are different. Specifically, in the embodiment, the temperature of the light shielding material 545 that overlaps the mold 590 is lower, while the temperature of the light shielding material 545 that overlaps the opening 590p is higher.

As a result, the etching depth of the light shielding material 545 overlapping the mold 590 is less than the etching depth of the light shielding material 545 overlapping the opening 590p. In other words, the aforementioned light shielding pattern layer 140 is formed, and the distance d1 between the first surface 140f of the light shielding pattern layer 140 and the driver circuit substrate 110 is smaller than the distance d2 between the second surface 140s of the light shielding pattern layer 140 and the driver circuit substrate 110. However, the method which is used to etch the light shielding material 545 is not limited to the aforementioned embodiment. In other embodiments, the light shielding material 545 may be etched by methods such as laser cutting.

It is worth mentioning, in the embodiment, the opening 590p of the mold 590 has a width w1 which may be larger than 0.4 mm, while the width w1 depends on the thermal conductivity of materials of the mold 590. For instance, when the material of the mold 590 includes aluminum, and the thermal conductivity is 237 W/mK, the width w1 should be at least 10 mm in order to make the spacing s1 between the first surface 140f and the second surface 140s of the light shielding pattern layer 140 larger than or equal to 0.4 μm.

The mold 590 is removed after the light shielding pattern layer 140 is formed. Next, the adhesive material 170 (shown in FIG. 2A) is disposed on the light shielding pattern layer 140 and the light-emitting components 120, while the optical film 150 (shown in FIG. 2A) is adhered to the adhesive material 170 by lamination, spray coating or roller adhesion. Thus, the display device 100 illustrated in FIG. 2A is approximately completed.

In conclusion, a vision difference is created by the height difference between the first surface and the second surface of the light shielding pattern layer. Therefore, when the light-emitting components are turned off, the trademark or model pattern of the product can be shown on the display surface of the display device. Since the light-emitting components are exposed on the first surface and the second surface of the light shielding pattern layer, the light rays emitted by the light-emitting components will not be shielded by the light shielding pattern layer as the light-emitting components are turned on. Thus, the user's vision will not be affected. As a result, the trademark or the model pattern of the product can be shown on the display surface area of the display device without any limitation by the bezel of the display device, thereby increasing the area utilization of the display device.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A display device, comprising:
a driver circuit substrate;
a plurality of light-emitting components disposed on the driver circuit substrate and electrically connected to the driver circuit substrate; and
a light shielding pattern layer disposed on the driver circuit substrate, and the plurality of light-emitting components are exposed, wherein the light shielding pattern layer has a first surface and a second surface back on to the driver circuit substrate, and at least two of the plurality of light-emitting components are exposed on the first surface and the second surface separately, wherein a distance between the first surface and the driver circuit substrate is smaller than a distance between the second surface and the driver circuit substrate.

2. The display device of claim 1, wherein a spacing between the first surface and the second surface of the light shielding pattern layer is larger than 0.4 μm.

3. The display device of claim 1, wherein a spacing between the first surface and the second surface of the light shielding pattern layer is equal to 0.4 μm.

4. The display device of claim 1, wherein the first surface and the second surface of the light shielding pattern layer have a roughness, and the roughness is between 0.05 μm and 0.5 μm.

5. The display device of claim 1, wherein the first surface of the light shielding pattern layer shapes as words or trademark patterns.

6. The display device of claim 1, wherein each of the plurality of light-emitting components has a top surface backing on to the driver circuit substrate, and a distance between the second surface of the light shielding pattern layer and the driver circuit substrate is smaller than a distance between the top surface and the driver circuit substrate, wherein a spacing is between the second surface and the top surface, and the spacing is larger than 1 μm.

7. The display device of claim 1, further comprising:
a plurality of pads disposed on the plurality of light-emitting components separately and located between the driver circuit substrate and the plurality of light-emitting components, wherein the plurality of light-emitting components are electrically connected to the driver circuit substrate through the plurality of pads, and each of the plurality of pads has a top surface backing on to the driver circuit substrate, wherein a distance between the top surface and the driver circuit substrate is smaller than a distance between the first surface and driver circuit substrate.

8. The display device of claim 1, further comprises:
an optical film disposed on the light shielding pattern layer and the plurality of light-emitting components and covering the first surface and the second surface of the light shielding pattern layer and the plurality of light-emitting components.

9. The display device of claim 8, further comprises:
an adhesive material disposed on the light shielding pattern layer and located between the optical film and the driver circuit substrate.

10. The display device of claim 1, wherein the light shielding pattern layer is an opaque encapsulation layer, and the encapsulation layer is distributed between the plurality of light-emitting components.

11. A display device, comprising:
a driver circuit substrate;
a plurality of light-emitting components disposed on the driver circuit substrate and electrically connected to the driver circuit substrate; and
a light shielding pattern layer disposed on the driver circuit substrate, and the plurality of light-emitting components are exposed, wherein the light shielding pattern layer has a first surface and a second surface back on to the driver circuit substrate, and at least two of the plurality of light-emitting components are exposed on the first surface and the second surface separately,
wherein a first spacing between the first surface and the second surface of the light shielding pattern layer is larger than 0.4 μm.

12. The display device of claim 11, wherein the first surface of the light shielding pattern layer shapes as words or trademark patterns.

13. The display device of claim 11, wherein each of the plurality of light-emitting components has a top surface backing on to the driver circuit substrate, and a distance between the second surface of the light shielding pattern layer and the driver circuit substrate is smaller than a distance between the top surface and the driver circuit substrate, wherein a second spacing is between the second surface and the top surface, and the second spacing is larger than 1 μm.

14. The display device of claim 11, further comprises:
an optical film disposed on the light shielding pattern layer and the plurality of light-emitting components and covering the first surface and the second surface of the light shielding pattern layer and the plurality of light-emitting components.

15. The display device of claim 14, further comprises:
an adhesive material disposed on the light shielding pattern layer and located between the optical film and the driver circuit substrate.
